(19) United States
(12) Patent Application Publication
(10) Pub. No.: US 2026/0198053 A1
(43) Pub. Date: Jul. 9, 2026

(54) TRANSISTOR DEVICE AND MANUFACTURING METHOD THEREOF

(71) Applicant: ProAsia Semiconductor Corporation, Hsinchu City (TW)

(72) Inventors: Ming-Chi Kuo, Hsinchu City (TW); Pin-Yen Huang, Hsinchu City (TW); I-Tai Li, Hsinchu City (TW)

(21) Appl. No.: 19/264,267

(22) Filed: Jul. 9, 2025

(30) Foreign Application Priority Data
Jan. 8, 2025 (TW) 114100763

(51) Int. Cl. H10D 62/60; H01L 21/04; H10D 30/01; H10D 30/66; H10D 62/10; H10D 62/832

(52) U.S. Cl. CPC H10D 62/60; H10D 30/0291; H10D 30/66; H10D 62/102; H10D 62/8325; H10P 30/2042; H10P 30/22; H10P 30/222

(57) ABSTRACT

A transistor device and a manufacturing method thereof are provided. The manufacturing method for a transistor device includes the following steps: first, providing a first conductive type epitaxial layer disposed on a substrate. Second, a first photomask is used to implant a second conductive type ion into the first conductive type epitaxial layer to form a second conductive type body region. Then, a first conductive type ion implantation is performed on the second conductive type body region using a second photomask to form a first conductive type heavily doped region in the second conductive type body region. Finally, a second conductive type tilt ion implantation is performed on the second conductive type body region on both sides of the first conductive type heavily doped region using the second photomask to form two in-situ self-aligned second conductive type doped channels in the second conductive type body region on both sides of the first conductive type heavily doped region.

### CROSS-REFERENCES TO RELATED APPLICATIONS

This application claims the benefit of priority to Taiwanese Patent Application No. 114100763 filed on Jan. 8, 2025, which is hereby incorporated by reference in its entirety.

### BACKGROUND OF THE INVENTION

### Field of the Invention

This invention relates to a transistor device and a manufacturing method thereof, and in particular to a transistor device with low channel resistance and a manufacturing method thereof.

### Descriptions of the Related Art

A Power Metal Oxide Semiconductor Field-Effect Transistor (Power MOSFET), generally referred to as a power transistor, is a field-effect transistor widely used in analog and digital circuits. It has become the mainstream power device, dominating the market and frequently applied in various electronic power applications. In particular, power transistor devices made using silicon carbide (SiC) substrates have gradually replaced traditional silicon-based power devices, finding widespread use in high-voltage, high-temperature, and low on-resistance high-speed power devices.

For example, compared to traditional silicon-based Insulated Gate Bipolar Transistors (IGBTs), silicon carbide transistor devices offer higher breakdown voltage, enabling lower on-resistance with smaller device sizes. Moreover, due to the higher electron mobility of silicon carbide materials, silicon carbide transistor devices can achieve faster switching speeds, making them more suitable for next-generation high-voltage and high-frequency applications. Therefore, optimizing the power transistor structure to further reduce on-resistance (Ron) and enhance switching speed is a critical challenge that the industry urgently needs to address.

### SUMMARY OF THE INVENTION

The primary objective of this invention is to provide an innovative transistor device and a manufacturing method thereof, featuring two in-situ self-aligned tilted ion implantation channels. This design reduces channel length while avoiding issues caused by photolithography misalignment, such as short-channel effects, thereby achieving reduced on-resistance and improved switching speed for enhanced device performance.

To achieve the above objective, this invention provides a manufacturing method for a transistor device, comprising the following steps: first, providing a first conductive type epitaxial layer disposed on a substrate. Second, a first photomask is used to implant a second conductive type ion into the first conductive type epitaxial layer to form a second conductive type body region. Then, a first conductive type ion implantation is performed on the second conductive type body region using a second photomask to form a first conductive type heavily doped region in the second conductive type body region. Finally, a second conductive type tilt ion implantation is performed on the second conductive type body region on both sides of the first conductive type heavily doped region using the second photomask to form two in-situ self-aligned second conductive type doped channels in the second conductive type body region on both sides of the first conductive type heavily doped region

In one embodiment of the manufacturing method of the transistor device of this invention, the second conductive type tilt ion implantation has an implantation tilt angle relative to the vertical normal, the implantation tilt angle ranging from 35° to 45°.

In one embodiment of the manufacturing method of the transistor device of this invention, the second conductive type tilt ion implantation is performed with a doping energy of 20 to 100 keV.

In one embodiment of the manufacturing method of the transistor device of this invention, each of the in-situ self-aligned second conductive type doped channels has an aluminum (Al) ion doping concentration per unit area of 1E13 to 5E13 cm⁻².

In one embodiment of the manufacturing method of the transistor device of this invention, the step of providing a first conductive type epitaxial layer is to provide an N-type lightly doped silicon carbide epitaxial layer.

In one embodiment of the manufacturing method of the transistor device of this invention, the step of forming a second conductive type body region is to form a P-type lightly doped body region with a doping concentration per unit area of 1E12 to 1E13 cm⁻².

In one embodiment of the manufacturing method of the transistor device of this invention, the step of forming a first conductive type heavily doped region is to form an N-type heavily doped region with a doping concentration of 1E19 to 1E20 cm⁻³.

To achieve the above objective, this invention provides a transistor device comprising a silicon carbide substrate, an N-type drift layer, a P-type body region, an N-type heavily doped region, and two in-situ self-aligned P-type doped channels. The N-type drift layer is disposed on the silicon carbide substrate, the P-type body region is disposed on the N-type drift layer, the N-type heavily doped region is disposed in the P-type body region, and the two in-situ self-aligned P-type doped channels are disposed in the P-type body region on both sides of the N-type heavily doped region.

In one embodiment of the transistor device of this invention, each of the in-situ self-aligned P-type doped channels has an aluminum (Al) ion doping concentration per unit area of 1E13 to 5E13 cm⁻².

In one embodiment of the transistor device of this invention, each of the in-situ self-aligned P-type doped channels has a length of 0.5 to 1 micrometer (μm).

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 to FIG. 4 are schematic diagrams illustrating the manufacturing process of a power transistor device in one embodiment of this invention;

FIG. 5 is a cross-sectional schematic diagram of a power transistor device in one embodiment of this invention; and

FIG. 6 is a flowchart schematic diagram of the manufacturing process of a power transistor device in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

To reduce on-resistance (Ron) and enhance transistor device performance, several approaches can be considered. For example, thinning the silicon carbide substrate is one option; however, due to the high hardness of silicon carbide, the substrate thinning process is inefficient and costly. Another feasible approach is to shorten the channel length to reduce channel resistance for lowering on-resistance and increasing switching speed, effectively reducing switching losses. The following Equation 1 represents the formula for channel resistance (R_{CH}):

$${R}_{C H} = \frac{L * {t}_{o x}}{W * {μ}_{n} * {ε}_{0} * {ε}_{γ} * ( {V}_{G S , u s e} - {V}_{t h} )} \qquad ( Equation 1 )$$

Where:
R_{CH} represents the channel resistance, indicating the resistance of the channel region of the transistor device.
L represents the channel length, i.e., the distance between the source and the drain.
tₒₓ represents the oxide layer thickness, typically the thickness of the gate oxide layer.
W represents the channel width, indicating the lateral dimension of the transistor device's channel.
μₙ represents electron mobility, describing the ability of electrons to move in the semiconductor.
ε₀ represents the vacuum dielectric constant, approximately 8.85×10⁻¹² F/m.
εᵣ represents the relative dielectric constant of the oxide layer (e.g., approximately 3.9 for silicon dioxide).
V_{GS,use} represents the gate-source voltage applied between the gate and source under operating conditions.
Vₜₕ represents the threshold voltage, i.e., the gate-source voltage at which the transistor device begins to conduct.

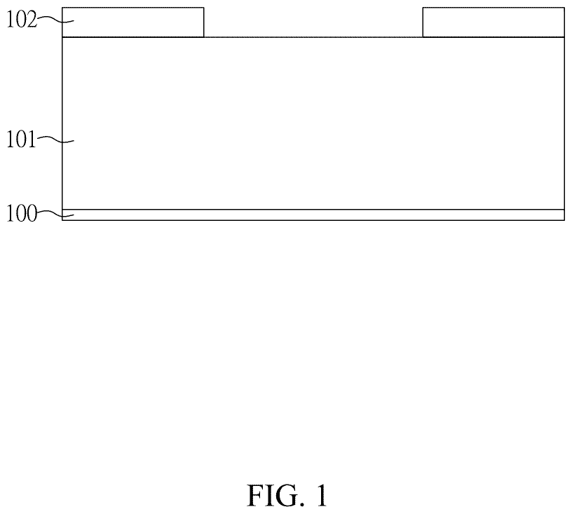

From Equation 1, it is evident that channel resistance (R_{CH}) is directly proportional to channel length (L). Therefore, reducing the channel length (L) can decrease channel resistance (R_{CH}), thereby lowering on-resistance (Ron). Please refer to FIG. 1 to FIG. 4, which illustrate cross-sectional schematic diagrams of the manufacturing process of a power transistor device in one embodiment of this invention. Specifically, this power transistor device is a Vertical Diffused Metal Oxide Semiconductor Field Effect Transistor (VDMOSFET), as detailed below. The power transistor device includes a substrate 100. In this embodiment, the substrate 100 is a first conductive type silicon carbide substrate, such as an N-type heavily doped silicon carbide substrate, to provide a low-resistance channel. Disposed on the substrate 100 is a first conductive type epitaxial layer 101, which may be, but is not limited to, an N-type lightly doped silicon carbide epitaxial layer serving as an N-type drift layer. This layer has a thickness ranging from a few micrometers (μm) to tens of micrometers (μm) and a low doping concentration of 1E14 to 1E16 cm⁻³ enabling the power transistor device to withstand high voltages. In a specific embodiment, the thickness and doping concentration of the first conductive type epitaxial layer 101 are designed based on the voltage withstand requirements of the power transistor device. Next, a photoresist is deposited on the first conductive type epitaxial layer 101, and after a photolithography and etching process, a patterned first photomask 102 is formed on the first conductive type epitaxial layer 101, as shown in FIG. 1.

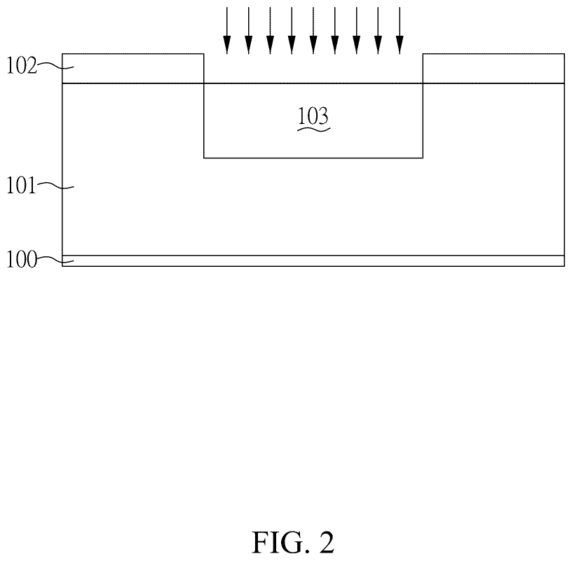

Please refer to FIG. 2, which illustrates performing a blanket second conductive type ion implantation on the first conductive type epitaxial layer 101 using the patterned first photomask 102 as an implantation mask, thereby defining and forming a second conductive type body region 103 in the first conductive type epitaxial layer 101. In a specific embodiment, the second conductive type body region 103 is a P-type lightly doped body region, with typical P-type dopants being aluminum (Al) or boron (B). Preferably, since aluminum (Al) forms a shallower acceptor level and offers good thermal stability, this invention uses aluminum (Al) as the primary P-type dopant, with a doping concentration per unit area of 1E12 to 1E13 cm⁻².

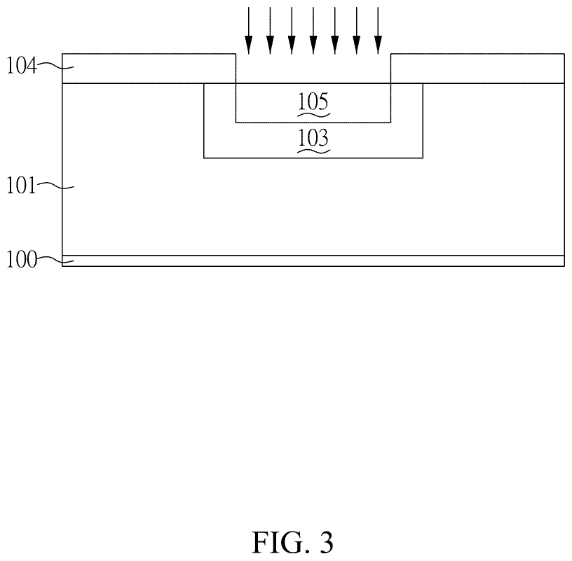

Please refer to FIG. 3, which illustrates depositing and forming a patterned second photomask 104 on the first conductive type epitaxial layer 101. Next, a blanket first conductive type ion implantation is performed on the second conductive type body region 103 using the patterned second photomask 104 as an implantation mask, thereby defining and forming a first conductive type heavily doped region 105 in the second conductive type body region 103. In a specific embodiment, the first conductive type heavily doped region 105 is an N-type heavily doped region, with typical N-type dopants of nitrogen (N) or phosphorus (P). Preferably, this invention uses nitrogen (N) as the primary N-type dopant, with a doping concentration of 1E19 to 1E20 cm⁻³, ensuring low resistance in the source region of the device and forming a good ohmic contact with the source metal.

Next, the manufacturing process for the channel layer of the power transistor device is performed. It should be noted that, as mentioned earlier, the technical approach of this invention to reduce channel resistance (Rc) is based on reducing channel length (L) according to Equation 1. There are two ways to achieve a reduced channel length. One approach is to use two photomasks with two exposure and development steps during the process to define the channel length (L). However, in practical applications, this method must account for process errors due to photomask misalignment, which can cause variations in channel length between adjacent active regions, leading to short-channel effects (e.g., Drain-induced Barrier Lowering, DIBL) that affect electrical properties, such as a reduction in the gate-source threshold voltage (Vₜₕ). Therefore, when using this photomask to define the channel length, the extent to which the channel length can be reduced is limited by the precision of photomask overlay.

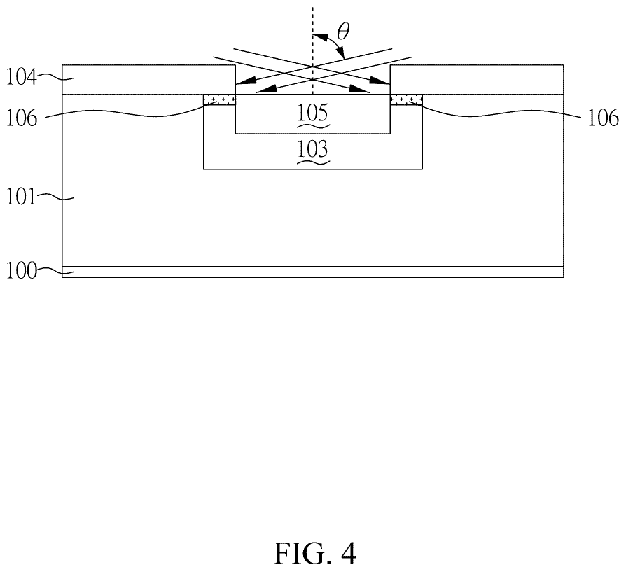

In view of this, to avoid the limitations on channel length reduction caused by short-channel effects, this invention discloses an in-situ self-aligned channel manufacturing method. Please refer to FIG. 4. After forming the first conductive type heavily doped region 105, this invention simultaneously uses the second photomask 104 to perform a second conductive type tilt ion implantation on the second conductive type body region 103 on both sides of the first conductive type heavily doped region 105, forming two in-situ self-aligned second conductive type doped channels 106 in the second conductive type body region 103 on both sides of the first conductive type heavily doped region 105. As shown in FIG. 4, the second conductive type tilt ion implantation has an implantation tilt angle θ relative to the vertical normal, with the implantation tilt angle θ ranging from 35° to 45°. On the other hand, in a specific embodiment, the second conductive type tilt ion implantation is performed using P-type ions, such as aluminum (Al) ions, with a doping concentration per unit area of 1E13 to 5E13 cm⁻² and a doping energy of 20 to 250 keV, preferably 20 to 100 keV. It should be noted that the second conductive type tilt ion implantation is sufficient to provide adequate P-type carriers at the surface of the second conductive type body region 103. This enables the formation of a continuous inversion layer at the surface of the second conductive type body region 103 when the gate voltage of the power transistor device exceeds the threshold voltage (Vₜₕ), thereby forming the second conductive type doped channels 106. In a preferred embodiment, the length of the in-situ self-aligned second conductive type doped channels 106 formed using the disclosed process can be substantially reduced to 0.5 to 1 micrometer (μm), or even shorter, while avoiding issues arising from photomask overlay errors.

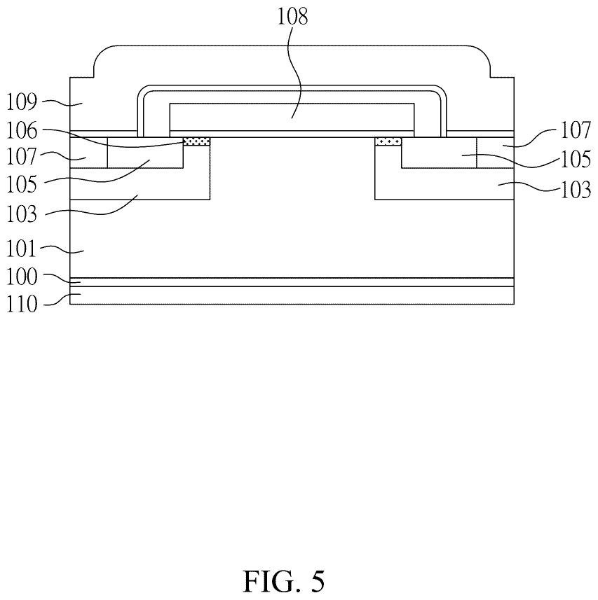

As shown in FIG. 5, preferably, to further reduce contact resistance with the metal and suppress the base resistance of the parasitic PNP Bipolar Junction Transistor (BJT), a second conductive type doped region 107 is further formed in the first conductive type heavily doped region 105. Specifically, this may be a P-type heavily doped region. Subsequently, a gate metal 108, a source metal 109, and a drain metal 110 are respectively formed on the transistor device through metal contact processes for the gate region, source region, and backside drain region, thereby completing the final structure of the power transistor device of this invention. Please refer to FIG. 5, which illustrates a cross-sectional schematic diagram of the structure of the power transistor device of this invention.

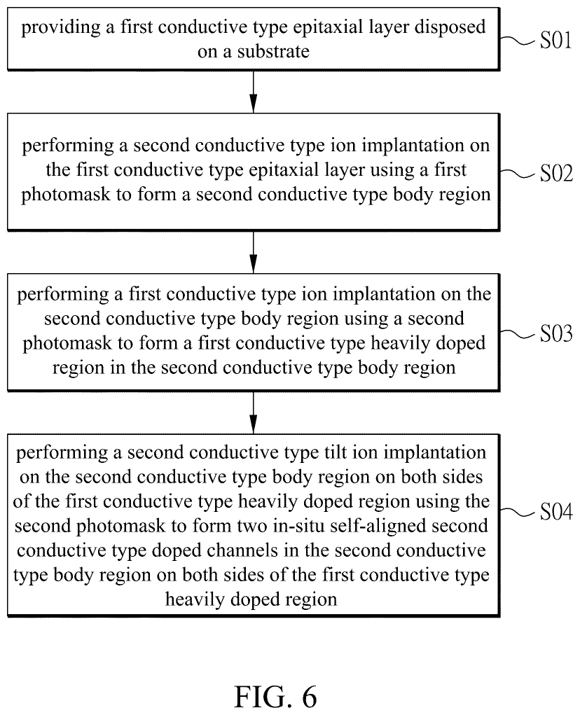

Please refer to FIG. 6, which illustrates a flowchart schematic diagram of the manufacturing process of the power transistor device of this invention. First, in step S01, a first conductive type epitaxial layer is provided, disposed on a substrate. In step S02, a second conductive type ion implantation is performed on the first conductive type epitaxial layer using a first photomask to form a second conductive type body region. Next, in step S03, a first conductive type ion implantation is performed on the second conductive type body region using a second photomask to form a first conductive type heavily doped region in the second conductive type body region. Finally, in step S04, a second conductive type tilt ion implantation is performed on the second conductive type body region on both sides of the first conductive type heavily doped region using the second photomask to form two in-situ self-aligned second conductive type doped channels in the second conductive type body region on both sides of the first conductive type heavily doped region. The descriptions of the related components in the aforementioned process steps can be referred to the above content and will not be repeated here.

In summary, this invention does not use photomask overlay to control the channel length of the inversion region of the device. Instead, after the first conductive type (N+) ion implantation process, an additional tilted second conductive type ion implantation process is performed to form a channel layer that is in-situ self-aligned to the N+ heavily doped region, thereby precisely controlling the reduced channel length. This approach significantly reduces on-resistance while avoiding issues such as short-channel effects caused by photolithography misalignment, effectively enhancing device performance, such as switching speed.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A manufacturing method for a transistor device, comprising:
providing a first conductive type epitaxial layer disposed on a substrate;
performing a second conductive type ion implantation on the first conductive type epitaxial layer using a first photomask to form a second conductive type body region;
performing a first conductive type ion implantation on the second conductive type body region using a second photomask to form a first conductive type heavily doped region in the second conductive type body region; and
performing a second conductive type tilt ion implantation on the second conductive type body region on both sides of the first conductive type heavily doped region using the second photomask to form two in-situ self-aligned second conductive type doped channels in the second conductive type body region on both sides of the first conductive type heavily doped region.

2. The manufacturing method for a transistor device of claim 1, wherein the second conductive type tilt ion implantation has an implantation tilt angle relative to a vertical normal, the implantation tilt angle ranging from 35° to 45°.

3. The manufacturing method for a transistor device of claim 1, wherein the second conductive type tilt ion implantation is performed with a doping energy of 20 to 100 keV.

4. The manufacturing method for a transistor device of claim 1, wherein each of the in-situ self-aligned second conductive type doped channels has an aluminum (Al) ion doping concentration per unit area of 1E13 to 5E13 cm⁻².

5. The manufacturing method for a transistor device of claim 1, wherein the step of providing a first conductive type epitaxial layer is to provide an N-type lightly doped silicon carbide epitaxial layer.

6. The manufacturing method for a transistor device of claim 1, wherein the step of forming a second conductive type body region is to form a P-type lightly doped body region with a doping concentration per unit area of 1E12 to 1E13 cm⁻².

7. The manufacturing method for a transistor device of claim 1, wherein the step of forming a first conductive type heavily doped region is to form an N-type heavily doped region with a doping concentration of 1E19 to 1E20 cm⁻³.

8. A transistor device, comprising:
a silicon carbide substrate;
an N-type drift layer disposed on the silicon carbide substrate;
a P-type body region disposed on the N-type drift layer;
an N-type heavily doped region disposed in the P-type body region; and
two in-situ self-aligned P-type doped channels disposed in the P-type body region on both sides of the N-type heavily doped region.

9. The transistor device of claim 8, wherein each of the in-situ self-aligned P-type doped channels has an aluminum (Al) ion doping concentration per unit area of 1E13 to 5E13 cm⁻².

10. The transistor device of claim 8, wherein each of the in-situ self-aligned P-type doped channels has a length of 0.5 to 1 micrometer (μm).
